(19) United States
(12) Patent Application Publication
(10) Pub. No.: US 2026/0226650 A1
(43) Pub. Date: Aug. 6, 2026

(54) APPARATUS AND METHOD FOR GROWING SILICON SINGLE CRYSTAL INGOT

(71) Applicant: SK SILTRON CO., LTD., Gumi-si Gyeongsangbuk-do (KR)

(72) Inventor: Hye Sun BANG, Gumi-si (KR)

(21) Appl. No.: 19/151,016

(22) PCT Filed: Feb. 13, 2023
(86) PCT No.: PCT/KR2023/002058

§ 371 Date: Jul. 25, 2025

(30) Foreign Application Priority Data
Feb. 10, 2023 (KR) 10-2023-0017907

(51) Int. Cl. C30B 15/10; C30B 15/00; C30B 15/02; C30B 15/16; C30B 15/20; C30B 15/30; C30B 17/00; C30B 29/06

(52) U.S. Cl. CPC C30B 15/10; C30B 15/007; C30B 15/02; C30B 15/16; C30B 15/206; C30B 15/30; C30B 17/00; C30B 29/06

(57) ABSTRACT

Provided in an embodiment is an apparatus for growing a silicon (Si) single crystal ingot, comprising: a chamber; a crucible, which is provided inside the chamber and accommodates Si melt; a heating unit provided at the periphery and/or the lower portion of the crucible; a first water cooling tube fixed at the upper portion of the inside of the chamber and arranged at the periphery of a Si single crystal ingot grown from the Si melt and raised; a heat-insulating member provided in an adjacent area of the crucible; a heat shield provided on the upper portion of the crucible and the heat-insulating member; an elevation member for elevating the heat shield; a second water cooling tube connected to the elevation member so as to be elevated upward and downward, and provided on the heat shield; and a current measurement unit for measuring the current between the elevation member and the heat-insulating member.

### CROSS-REFERENCE TO RELATED PATENT APPLICATIONS

This application is a U.S. National Stage Application under 35 U.S.C. § 371 of PCT Application No. PCT/KR2023/002058, filed Feb. 13, 2023, which claims priority to Korean Patent Application No. 10-2023-0017907, filed Feb. 10, 2023, whose entire disclosures are hereby incorporated by reference.

### TECHNICAL FIELD

The present disclosure relates to an apparatus and method for growing a silicon single crystal ingot, and more particularly, to improving the quality of a silicon single crystal ingot that is grown and drawn upward by accurately controlling the length of a water cooling pipe.

### BACKGROUND ART

A silicon wafer is typically manufactured through a single crystal growth process of producing a single crystal ingot, a slicing process of slicing the single crystal ingot to obtain a thin disc-shaped wafer, a lapping process of removing damage to the wafer caused by mechanical processing during the slicing, a polishing process of mirror-polishing the wafer, and a cleaning process of removing a polishing agent or foreign matter from the mirror-polished wafer.

Among the above-described processes, the process of growing a silicon single crystal may be performed using the Czochralski method (hereinafter referred to as the CZ method).

When a single crystal ingot is fabricated using the CZ method, a growth furnace charged with high-purity polycrystalline silicon (poly-Si) may be heated at a high temperature to melt a raw material, a seed crystal may be introduced from above into the silicon (Si) melt, and then a silicon single crystal may be grown and drawn upward.

In order to improve the productivity of a silicon single crystal ingot, the length of a basic section tends to be increased. As the length of the silicon single crystal ingot increases, the initial charge also increases. However, in the related art, because a water cooling pipe is fixed to a chamber, a space in an upper hot zone, particularly in a heat shield, is limited. Thus, when a polycrystalline silicon chunk is charged into a crucible, the amount of polycrystalline silicon charged is limited, which restricts the initial charge and makes it difficult to improve productivity.

In addition, in order to control the crystal quality, cooling conditions of the silicon single crystal ingot need to be adjusted. The cooling rate of the silicon single crystal ingot may be controlled by adjusting the position of a water cooling pipe relative to a solid-liquid interface. As a method for adjusting the position of the water cooling pipe, a water cooling pipe having a relatively short or long length may be used to arbitrarily adjust the position of the water cooling pipe.

However, the method of adjusting the length of the water cooling pipe has a drawback in that multiple water cooling pipes need to be provided according to the adjusted length. In addition, the use of water cooling pipes having different lengths causes the inconvenience of replacing the water cooling pipes whenever process conditions are changed. When the water cooling pipes are replaced or auxiliary equipment is installed, equipment downtime occurs during the replacement or installation, thereby reducing productivity.

To address such issues, Korean Patent Laid-Open Publication No. 10-2021-0089395 (published on Jul. 16, 2021) discloses a technique in which, in addition to a fixed water cooling pipe, a movable water cooling pipe is further provided to increase the overall length of the water cooling pipe.

However, it is difficult to accurately control and measure the movement distance of the movable water cooling pipe.

### DISCLOSURE

### Technical Problem

The present disclosure has been made in an effort to solve the above-described problems, and an aspect of the present disclosure is to provide an apparatus and method for growing a silicon single crystal ingot, which enable accurate measurement of the length of a movable water cooling pipe.

### Technical Solution

An embodiment provides a silicon single crystal ingot growth apparatus including a chamber, a crucible provided in the chamber and configured to contain a silicon (Si) melt, a heater provided in at least one of a region around the crucible or a region below the crucible, a first water cooling pipe fixedly provided in an upper region of the chamber and disposed around a silicon single crystal ingot grown and drawn upward from the silicon melt, a thermal insulation member provided in a region around the crucible, a heat shield provided above the crucible and the thermal insulation member, a lifting member configured to raise and lower the heat shield, a second water cooling pipe connected to the lifting member to move up and down in an upward-downward direction and disposed above the heat shield, and a current measuring unit configured to measure a current between the lifting member and the thermal insulation member.

The lifting member may include a fixing pin fixed to an upper portion of the heat shield, an extension plate fixed to the upper portion of the heat shield by the fixing pin and extending in a horizontal direction from the fixing pin, a pipe extending upward from the extension plate to the outside of the chamber, and a body extending from the pipe in an inward direction of the chamber, and the second water cooling pipe may extend downward from an inner side of the body.

The pipe and the thermal insulation member may include electrically conductive materials, and the current measuring unit may further include a conducting wire interconnecting the electrically conductive materials of the pipe and the thermal insulation member and an ammeter provided on the conducting wire.

A first height of a lower end of the first water cooling pipe may be equal to or lower than a second height of an upper end of the second water cooling pipe and may be higher than a third height of a lower end of the second water cooling pipe.

Each of the first and second water cooling pipes may have a shape surrounding the periphery of the silicon single crystal ingot drawn upward, and a width of the second water cooling pipe in a lateral direction may be greater than a width of the first water cooling pipe in the lateral direction.

When the lifting member moves to the lowest position, a lower end of the heat shield may come into contact with an upper end of the thermal insulation member.

The extension plate may include a first portion and a third portion provided parallel to each other and a second portion interconnecting the first and third portions, and the first portion may include a first hole formed therein to allow the fixing pin to be inserted thereinto.

When the first portion of the extension plate comes into full contact with an upper end of the heat shield, a certain magnitude of current flows, from which it may be determined that the first portion is seated on the upper end of the heat shield.

The third portion of the extension plate may include a second hole formed therein to allow the pipe to be inserted thereinto.

The extension plate and the pipe may be electrically conductive, the first portion of the extension plate may be in contact with an upper end of the heat shield, and an outer wall of the pipe may be in contact with an inner wall of the second hole in the third portion of the extension plate.

Each of the pipe, the fixing pin, and the extension plate may be formed of stainless steel or molybdenum.

Another embodiment provides a silicon single crystal ingot growth method including lowering, in an upper region of a chamber, a heat shield to a region above a crucible containing a silicon melt using a lifting member, bringing the heat shield into contact with an upper portion of a thermal insulation member provided in a region outside the crucible, measuring a first magnitude of a current flowing from the lifting member to the thermal insulation member via the heat shield, and measuring a second magnitude of the current resulting from further descent of the lifting member to measure, based on a difference between the second magnitude and the first magnitude of the current, a height after the further descent of the lifting member.

Dipping a seed into the silicon melt to grow a silicon single crystal ingot after measuring the second magnitude of the current flowing from the lifting member to the thermal insulation member via the heat shield may be included.

When a resistivity of the lifting member is represented by ρ, a cross-sectional area of the lifting member in a horizontal direction is represented by S, the first magnitude of the current is represented by I1, the second magnitude of the current is represented by I2, and a voltage applied to the current flowing from the lifting member to the thermal insulation member via the heat shield is represented by V, a movement distance L of the lifting member from measuring the first magnitude of the current to measuring the second magnitude of the current may be calculated using the following Equation 1:

$$L = ( S / ρ ) \times ( V / ( I 2 - I 1 ) ) . \qquad < Equation 1 >$$

In the silicon single crystal ingot growth method, based on the calculated movement distance L of the lifting member in an upward-downward direction, a change in length of the second water cooling pipe may be calculated, and a total length of the first water cooling pipe and the second water cooling pipe in a vertical direction may be obtained, wherein the total length of the first water cooling pipe and the second water cooling pipe in the vertical direction may be a distance from an upper end of the first water cooling pipe to a lower end of the second water cooling pipe.

### Advantageous Effects

According to the above-described silicon single crystal ingot growth apparatus and method, the total length of the water cooling pipes may be accurately controlled by providing the movable second water cooling pipe in addition to the fixed first water cooling pipe, calculating the movement distance of the pipe of the lifting member based on the change in the magnitude of the current according to movement of the lifting member, and determining the movement distance of the second water cooling pipe based thereon. Accordingly, the section in which the silicon single crystal ingot begins to be cooled while passing through a vertical level at which the silicon single crystal ingot overlaps the water cooling pipes in the horizontal direction may be adjusted in advance.

### DESCRIPTION OF DRAWINGS

FIG. 1 is a view showing an apparatus for growing a silicon single crystal ingot according to an embodiment of the present disclosure.

FIG. 2 is a view showing the lifting member in FIG. 1 in detail.

FIG. 3 is a view showing the operation of a first portion of an extension plate and a first stopper of a fixing pin of the lifting member in FIG. 2 in detail.

FIGS. 4A to 4C are views showing movement of the lifting member in FIG. 2 in an upper region of a chamber of the silicon single crystal ingot growth apparatus in FIG. 1.

FIG. 5 shows a method of growing a silicon single crystal ingot using the silicon single crystal ingot growth apparatus in FIG. 1.

FIGS. 6(a) and (b) are views showing measurement of a current according to movement of a pipe.

### BEST MODE

The present disclosure will now be described more fully hereinafter with reference to the accompanying drawings, in which various embodiments are shown.

The examples, however, may be embodied in many different forms and should not be construed as being limited to the embodiments set forth herein. Rather, these embodiments are provided so that this disclosure will be more thorough and complete, and will more fully convey the scope of the disclosure to those skilled in the art.

In addition, relational terms, such as “first,” “second,” “on,” and “under,” are used only to distinguish between one subject or element and another subject or element, without necessarily requiring or involving any physical or logical relationship or sequence between the subjects or elements.

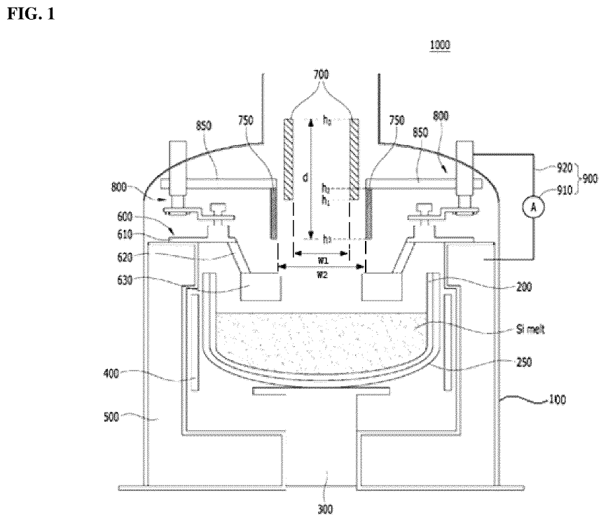

FIG. 1 is a view showing an apparatus for growing a silicon single crystal ingot according to an embodiment of the present disclosure.

As shown, the silicon single crystal ingot growth apparatus 1000 according to the embodiment of the present disclosure includes a chamber 100 including a space defined therein to grow a silicon single crystal ingot from a silicon (Si) melt, an inner quartz crucible 200 and an outer graphite crucible 250 configured to contain the silicon (Si) melt, a lateral heater 400 and a bottom heater (not shown) configured to heat the inner quartz crucible 200 and the outer graphite crucible 250, a thermal insulation member 500 disposed outside the lateral heater 400 in a region around the quartz crucible 200 and the graphite crucible 250, a heat shield 600 disposed above the quartz crucible 200 and the graphite crucible 250 to block heat from the lateral heater 400 toward the silicon single crystal ingot, and a lower support member 300 configured to rotate the graphite crucible 250 and to move the graphite crucible 250 up and down.

In addition, the silicon single crystal ingot growth apparatus 1000 may include a first water cooling pipe 700 fixed at an upper position inside the chamber 100 and disposed around the silicon single crystal ingot that is grown and drawn upward from the silicon melt, a second water cooling pipe 750 provided below the heat shield 600, and a current measuring unit 900 configured to measure a current between the thermal insulation member 500 and a lifting member 800 to be described later.

The silicon single crystal ingot growth apparatus 1000 may further include a lifting member 800 configured to move the heat shield 600 up and down, and the second water cooling pipe 750 described above may be provided at a portion of the lifting member 800.

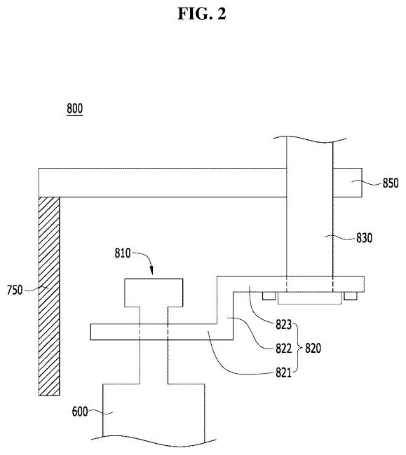

FIG. 2 is a view showing the lifting member in FIG. 1 in detail.

As shown, the lifting member 800 described above may include a fixing pin 810 fixed to an upper portion of the heat shield 600, an extension plate 820 fixed to the upper portion of the heat shield 600 by the fixing pin 810 and extending in a horizontal direction from the fixing pin 810, and a pipe 830 extending upward from the extension plate 820 to the outside of the chamber 100. For example, a portion of the fixing pin 810 coupled to the upper portion of the heat shield 600 may have a bolt shape, and the bolt may be fastened to a portion of the heat shield 600 by rotation.

The fixing pin 810 may be regarded as a part of the heat shield 600, and a combination of the extension plate 820 and the pipe 830 may be referred to as the lifting member 800.

The heat shield 600 may include a through-hole formed at the center thereof, and a silicon single crystal ingot may be drawn upward through the through-hole. The fixing pin 810 described above may be fixed at at least two opposing positions on the upper portion of the heat shield 600.

The heat shield 600 may be provided as an integral structure. Depending on the function or operation thereof, the heat shield 600 may be divided into a seating portion 610 disposed on an upper end of the thermal insulation member 500, a shielding portion 630 disposed above the silicon melt, and a connecting portion 620 that interconnects the seating portion and the shielding portion. In this case, the fixing pin 810 may be fixed to the seating portion 610 of the heat shield 600.

The extension plate 820 may be provided with a step. For example, as shown, the extension plate 820 may include a first portion 821, a second portion 822, and a third portion 823. The first portion 821 and the third portion 823 may extend in a first direction, for example, in a horizontal direction, and the second portion 822 may extend in a second direction intersecting the first direction, for example, in a vertical direction, to interconnect the first portion 821 and the third portion 823. In this case, the vertical direction may be an upward-downward direction in which the silicon single crystal ingot is drawn upward.

In addition, the lifting member 800 may further include a body 850 extending from the pipe 830 toward the first water cooling pipe 700, that is, in an inward direction of the chamber 100. The body 850 may be integrally formed with the pipe 830 so as to move up and down together with the pipe 830.

As described above, the second water cooling pipe 750 may be provided at a portion of the lifting member 800. Referring to FIG. 2, the second water cooling pipe 750 may extend downward, that is, toward the crucibles 200 and 250, from an inner side of the body 850.

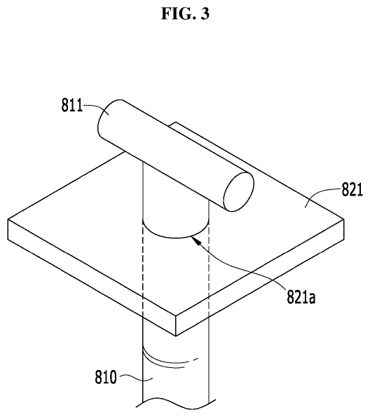

FIG. 3 is a view showing the operation of a first portion of the extension plate and a first stopper of the fixing pin of the lifting member in FIG. 2 in detail.

A first hole 821a may be formed in the first portion 821, and a first stopper 811 may be formed at an upper portion of the fixing pin 810. The fixing pin 810 may be inserted into the first hole 821a, and movement of the extension plate 820 may be restricted by the action of the first stopper 811.

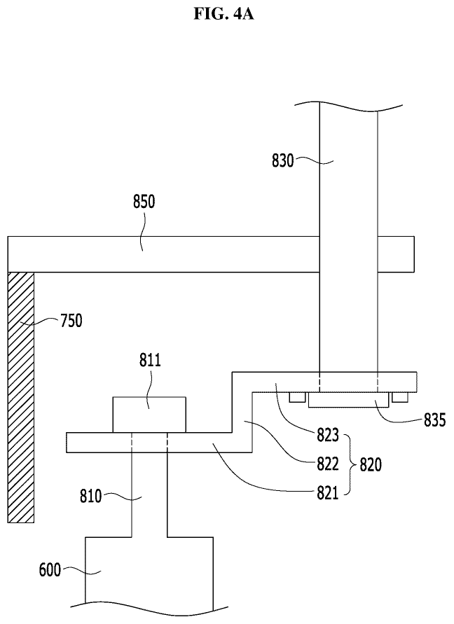

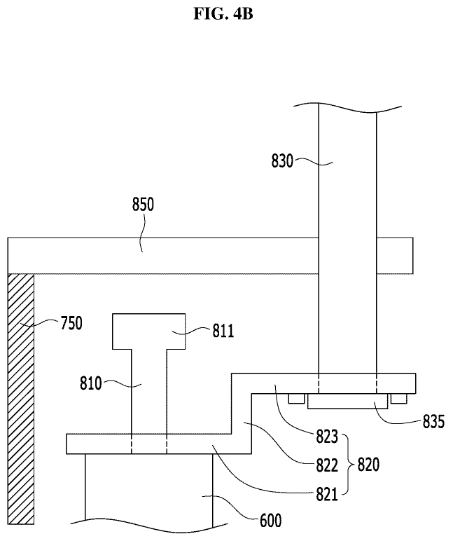

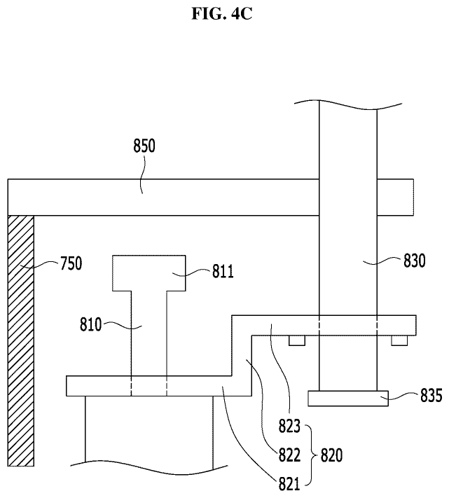

FIGS. 4A to 4C are views showing movement of the lifting member in FIG. 2 in an upper region of the chamber of the silicon single crystal ingot growth apparatus in FIG. 1, from which the movement of the second water cooling pipe according to the movement of the lifting member may be identified.

The pipe 830 of the lifting member 800 may move in the upward-downward direction to lift and lower the heat shield 600. In this case, the pipe 830 may move between the inside and the outside of the chamber 100 through a hole formed in an upper portion of the chamber 100.

In detail, in FIG. 4A, as the pipe 830 of the lifting member 800 descends, the extension plate 820, the fixing pin 810, and the heat shield 600 also gradually descend. In FIG. 4A, the heat shield 600 may be in a state of being spaced apart from the upper end of the thermal insulation member 500.

In this case, although not shown, a second hole (not shown) may be formed in the third portion 823 of the extension plate 820, and the pipe 830 may move in the upward-downward direction through the second hole in the third portion 823 of the extension plate.

The first portion 821 of the extension plate 820 is supported by the first stopper 811 of the fixing pin 810 coupled to the heat shield 600. In addition, a second region of the pipe 830 may be in a state of being inserted into the second hole formed in the third portion 823 of the extension plate 820. In this case, the third portion 823 of the extension plate 820 may be supported by a second stopper 835 provided at the pipe 830.

The pipe 830 may be provided with the second stopper 835 and the body 850. The width of the second stopper 835 provided at the pipe 830 may be greater than the diameter of the second hole formed in the third portion 823 of the extension plate 820. Therefore, when the pipe 830 moves up and down, the pipe 830 may be prevented from being completely separated upward from the extension plate 820 due to the action of the second stopper 835.

The pipe 830 and the extension plate 820 may be detachably coupled to each other. During movement of the lifting member 800, the pipe 830 and the extension plate 820 may remain coupled due to the action of the second stopper 835.

Subsequently, as shown in FIG. 4B, when the heat shield 600 no longer descends, for example, due to contact with the upper end of the thermal insulation member 500 described above, the fixing pin 810 may stop descending, while the extension plate 820 and the pipe 830 may continue to descend, and the body 850 and the second water cooling pipe 750 may also descend together.

Subsequently, as shown in FIG. 4C, as the extension plate 820 further descends, the first portion 821 of the extension plate 820 may come into contact with the heat shield 600, and the pipe 830 may further descend. In this case, the body 850 and the second water cooling pipe 750 connected to the pipe 830 may also descend together as the pipe 830 descends.

In FIGS. 4A to 4C, an outer wall of the pipe 830 may be in contact with an inner wall of the second hole in the third portion 823 of the extension plate 820. That is, the extension plate 820 and the pipe 830 may be electrically conductive, and the thermal insulation member 500, the heat shield 600, and the fixing pin 810 may also be electrically conductive. The electrically conductive material may be, for example, stainless steel or molybdenum.

Accordingly, while the pipe 830 further descends from the state shown in FIG. 4B, in which the first portion 821 of the extension plate 820 comes into contact with the heat shield 600, to the state shown in FIG. 4C, a current may flow from the pipe 830 through the extension plate 820, the heat shield 600, and the thermal insulation member 500. In addition, as shown in FIGS. 4B and 4C, the length of the current path becomes short as the pipe 830 descends. Therefore, as will be described later, the magnitude of the current may vary according to Ohm's law, and the movement distance of the pipe 830 may be calculated based on the change in the magnitude of the current. In addition, because the movement distance of the pipe 830 is equal to the movement distance of the body 850 and the second water cooling pipe 750, the movement distance of the second water cooling pipe 750 may be calculated. By summing the lengths of the first water cooling pipe 700 and the second water cooling pipe 750, the total length of the first and second water cooling pipes 700 and 750 disposed around the region in which the silicon single crystal ingot is drawn upward may be calculated and controlled.

The above-described current measurement unit 900 configured to measure the current and a change in the magnitude of the current may include an ammeter 910 connected to the pipe 830 and the thermal insulation member 500, which are made of an electrically conductive material, via a conducting wire 920.

In this embodiment, the fixed first water cooling pipe 700 may be disposed above the movable second water cooling pipe 750. In detail, as shown in FIG. 1, a first height h1 of the lower end of the first water cooling pipe 700 may be equal to or lower than a second height h2 of the upper end of the second water cooling pipe 750 and may be higher than a third height h3 of the lower end of the second water cooling pipe 750.

In addition, a distance d from a height h0 of the upper end of the first water cooling pipe 700 to the third height h3 of the lower end of the second water cooling pipe 750 may correspond to the above-described total length of the first and second water cooling pipes 700 and 750.

In addition, if the first water cooling pipe 700 and the second water cooling pipe 750 overlap each other in the vertical direction, damage may occur due to collision between the first and second water cooling pipes 700 and 750 when the movable second water cooling pipe 750 moves.

For this reason, the second water cooling pipe 750 may be located farther outward than the first water cooling pipe 700. That is, as shown in FIG. 1, each of the first and second water cooling pipes 700 and 750 may have a shape that surrounds the periphery of the silicon single crystal ingot that is drawn upward, and a width w2 of the second water cooling pipe 750 in a lateral direction may be greater than a width w1 of the first water cooling pipe 700 in the lateral direction.

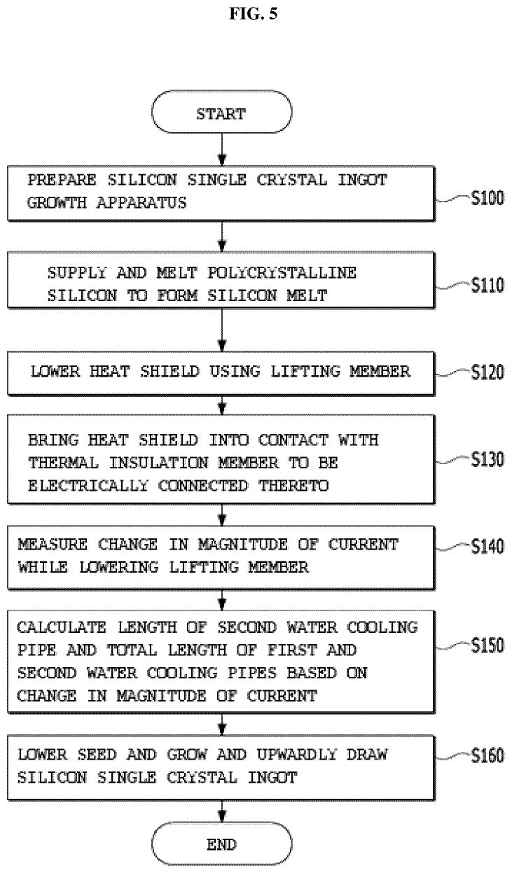

FIG. 5 shows a method of growing a silicon single crystal ingot using the silicon single crystal ingot growth apparatus in FIG. 1. In particular, the method relates to improving the quality of the silicon single crystal ingot by determining the length of the water cooling pipe and controlling cooling of the silicon single crystal ingot that is drawn upward.

First, the silicon single crystal ingot growth apparatus shown in FIG. 1 is prepared (S100). In this step, the heat shield 600, the lifting member 800, and the second water cooling pipe 750 may not yet be set in the chamber 100.

Various elements shown in FIG. 1, for example, the lateral heater 400 and the thermal insulation member 500, may be disposed in the chamber 100. In this case, the thermal insulation member 500 may have a structure in which multiple layers are stacked.

The thermal insulation member 500 is formed in a multilayered structure, and the heat shield 600 is provided separately.

Subsequently, polycrystalline silicon is injected into the crucibles, and the lateral heater 400 is operated to melt the polycrystalline silicon, thereby forming a silicon (Si) melt (S110).

Subsequently, before a silicon single crystal ingot is grown, the heat shield 600 is lowered to a region above the crucibles 200 and 250 using the lifting member 800.

In this case, as shown in FIGS. 4A to 4C, the pipe 830 of the lifting member 800 descends, and accordingly, the extension plate 820, the fixing pin 810, and the heat shield 600 also gradually descend (S120).

Because the outer wall of the pipe 830 is in contact with the inner wall of the second hole in the third portion 823 of the extension plate 820 as described above, the extension plate 820 may be electrically connected to the pipe 830.

Subsequently, when the state shown in FIG. 4B is reached, the heat shield 600 may come into contact with and be electrically connected to the upper end of the underlying thermal insulation member 500 (S130).

Subsequently, when the pipe 830 further descends to reach the state shown in FIG. 4C, the extension plate 820 may come into contact with and be electrically connected to the heat shield 600. Therefore, in this case, a current may be measured by the ammeter 910 connected to the pipe 830 and the thermal insulation member 500 via the conducting wire 910.

Subsequently, as the pipe 830 continues to descend, a change in the magnitude of the current may be measured by the ammeter 910 (S140). Based on the change in the magnitude of the current, the length of the second water cooling pipe may be calculated, and then the total length of the first and second water cooling pipes may be calculated (S150). Subsequently, when the total length of the first and second water cooling pipes reaches a target design value, a seed may be lowered, and a process of growing and upwardly drawing the silicon single crystal may be performed (S160).

Hereinafter, a process of calculating the length of the second water cooling pipe described above will be described in detail.

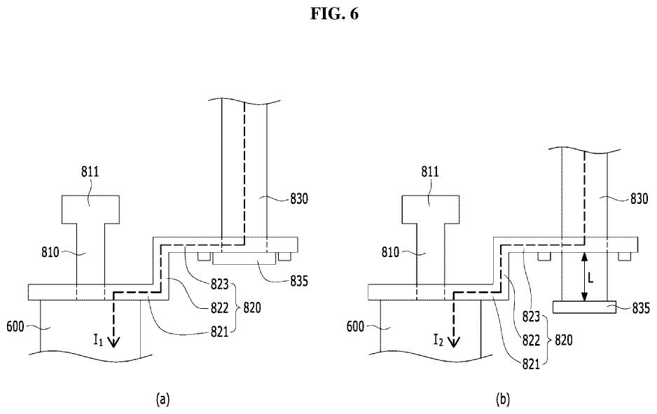

FIGS. 6a and 6b are views showing measurement of a current according to movement of the pipe. Hereinafter, a process of measuring a current according to movement of the pipe and obtaining the movement distance of the pipe based on the measured current will be described with reference to FIGS. 6a and 6b.

In FIG. 6a, the heat shield 600 is in contact with the upper end of the underlying thermal insulation member (not shown), the first portion 821 of the extension plate 820 is in contact with the upper end of the heat shield 600, and the second stopper 835 of the pipe 830 is in contact with and supports the third portion 823 of the extension plate 820. In the state shown in FIG. 6a, the magnitude of the current measured by the ammeter 910 is a first magnitude I₁.

Subsequently, as shown in FIG. 6b, when the pipe 830 further descends, the second stopper 835 of the pipe 830 may move away from the third portion 823 of the extension plate 820 in the state in which the heat shield 600 is in contact with the upper end of the underlying thermal insulation member (not shown) and the first portion 821 of the extension plate 820 is in contact with the upper end of the heat shield 600. In this case, because the outer wall of the pipe 830 is in contact with the inner wall of the second through-hole in the third portion 823 of the extension plate 820, the current may continue to flow, as indicated by the arrow. In the state shown in FIG. 6b, the magnitude of the current measured by the ammeter 910 is a second magnitude I₂.

Currents having different magnitudes are not necessarily measured only when the pipe 830 is positioned as shown in FIGS. 6(a) and 6(b). However, as long as a current flows through the pipe 830 and the pipe 830 is positioned at different vertical levels, currents having different magnitudes may be measured.

According to Ohm's law, when a voltage V is applied to a conducting wire having a resistance R, the magnitude I of a current flowing through the conducting wire may be obtained as follows.

$$I = V / R \qquad < Calculation Formula 1 >$$

In addition, the resistance R of a conducting wire having a resistivity ρ, a cross-sectional area S, and a length L may be obtained as follows.

$$R = ρ \times ( L / S ) \qquad < Calculation Formula 2 >$$

According to the above calculation formula, the length L of the conducting wire may be obtained as follows.

$$L = ( S / ρ ) \times R \qquad < Calculation Formula 3 >$$

In this case, the path of the current flowing through the pipe changes between the state shown in FIG. 6(a) and the state shown in FIG. 6(b), and accordingly, the magnitude of the current changes from the first magnitude I₁ to the second magnitude I₂. A change ΔI in the magnitude of the current is obtained as follows.

$$Δ I = {I}_{2} - {I}_{1}$$

In addition, a distance L by which the pipe 830 has moved from the state shown in FIG. 6(a) to the state shown in FIG. 6(b) as described above may be obtained as follows.

That is, according to Ohm's law described above,

R=V/ΔI=V/(I₂−I₁). Calculation Formula 3 above may be rearranged as follows.

$$L = ( S / ρ ) \times R = ( S / ρ ) \times ( V / ( {I}_{2} - {I}_{1} ) )$$

That is, the distance L by which the pipe has moved may be obtained from Equation 1 below.

$$L = ( S / ρ ) \times ( V / ( I 2 - I 1 ) ) \qquad < Equation 1 >$$

Here, L represents the difference in the current path between the state shown in FIG. 6(a) and the state shown in FIG. 6(b), that is, the distance by which the pipe 830 of the lifting member 800 has moved, S represents the cross-sectional area of the pipe 830 of the lifting member 800, p represents the resistivity of the pipe 830 of the lifting member 800, and V represents the voltage applied to the current flowing from the lifting member 800 to the thermal insulation member 500 via the heat shield 600.

In the silicon single crystal ingot growth apparatus 1000 in FIG. 1, the movement distance L of the pipe 830 may be obtained using Equation 1 based on the change in the magnitude of the current (ΔI=I₂−I₁) detected by the ammeter 910.

Once the movement distance L of the pipe 830 of the lifting member 800 between the state shown in FIG. 6(a) and the state shown in FIG. 6(b) is obtained through the process described above, the movement distance of the second water cooling pipe 750 may be determined. Accordingly, the total length of the first water cooling pipe 700 and the second water cooling pipe 750 may also be determined. In this case, the “total length” may be the distance d from the height h0 of the upper end of the first water cooling pipe 700 to the third height h3 of the lower end of the second water cooling pipe 750, and the silicon single crystal ingot that is drawn upward may begin to be cooled within the range of the distance d described above. Therefore, after the silicon single crystal ingot is grown, an operator may determine a desired length of the water cooling pipes and may move the pipe by the movement distance L so that the aforementioned distance d corresponds to the length of the water cooling pipes.

In addition, after the total length of the water cooling pipes is set through the process described above, a seed may be dipped into the silicon (Si) melt to grow the silicon single crystal ingot.

According to the above-described silicon single crystal ingot growth apparatus and method, the total length of the water cooling pipes may be accurately controlled by providing the movable second water cooling pipe in addition to the fixed first water cooling pipe, calculating the movement distance of the pipe of the lifting member based on the change in the magnitude of the current according to movement of the lifting member, and determining the movement distance of the second water cooling pipe based thereon. Accordingly, the section in which the silicon single crystal ingot is cooled while passing through a vertical level at which the silicon single crystal ingot overlaps the water cooling pipes in the horizontal direction may be adjusted in advance.

Even though the embodiments of the present disclosure have been described in more detail with reference to the accompanying drawings, the present disclosure is not necessarily limited to these embodiments, and may be variously modified and implemented without departing from the technical spirit of the present disclosure.

Therefore, the embodiments disclosed herein are not intended to limit the technical spirit of the present disclosure, but to describe the technical spirit, and the scope of the technical spirit of the present disclosure is not limited by these embodiments. Accordingly, it should be understood that the embodiments described above are illustrative in all respects and not restrictive. The protection scope of the present disclosure should be construed according to the scope of the claims, and all technical ideas within the scope equivalent thereto should be construed as being included in the scope of the present disclosure.

### INDUSTRIAL APPLICABILITY

The above-described silicon single crystal ingot growth apparatus and method may improve the quality of a silicon single crystal ingot that is grown and drawn upward by accurately controlling the length of water cooling pipes.

1. An apparatus for growing a silicon single crystal ingot, the apparatus comprising:
a chamber;
a crucible provided in the chamber, the crucible being configured to contain a silicon (Si) melt;
a heater provided in at least one of a region around the crucible or a region below the crucible;
a first water cooling pipe fixedly provided in an upper region of the chamber and disposed around a silicon single crystal ingot grown and drawn upward from the silicon melt;
a thermal insulation member provided in a region around the crucible;
a heat shield provided above the crucible and the thermal insulation member;
a lifting member configured to raise and lower the heat shield;
a second water cooling pipe connected to the lifting member to move up and down in an upward-downward direction and disposed above the heat shield; and
a current measuring unit configured to measure a current between the lifting member and the thermal insulation member.

2. The apparatus according to claim 1, wherein the lifting member includes:
a fixing pin fixed to an upper portion of the heat shield;
an extension plate fixed to the upper portion of the heat shield by the fixing pin and extending in a horizontal direction from the fixing pin;
a pipe extending upward from the extension plate to an outside of the chamber; and
a body extending from the pipe in an inward direction of the chamber, and
wherein the second water cooling pipe extends downward from an inner side of the body.

3. The apparatus according to claim 2, wherein the pipe and the thermal insulation member include electrically conductive materials, and
wherein the current measuring unit further includes a conducting wire interconnecting the electrically conductive materials of the pipe and the thermal insulation member and an ammeter provided on the conducting wire.

4. The apparatus according to claim 2, wherein a first height of a lower end of the first water cooling pipe is equal to or lower than a second height of an upper end of the second water cooling pipe and is higher than a third height of a lower end of the second water cooling pipe.

5. The apparatus according to claim 1, wherein each of the first and second water cooling pipes has a shape surrounding a periphery of the silicon single crystal ingot drawn upward, and
wherein a width of the second water cooling pipe in a lateral direction is greater than a width of the first water cooling pipe in the lateral direction.

6. The apparatus according to claim 2, wherein, when the lifting member moves to a lowest position, a lower end of the heat shield comes into contact with an upper end of the thermal insulation member.

7. The apparatus according to claim 2, wherein the extension plate includes a first portion and a third portion provided parallel to each other and a second portion interconnecting the first and third portions, and
wherein the first portion includes a first hole formed therein to allow the fixing pin to be inserted thereinto.

8. The apparatus according to claim 7, wherein the third portion of the extension plate includes a second hole formed therein to allow the pipe to be inserted thereinto.

9. The apparatus according to claim 8, wherein the extension plate and the pipe are electrically conductive,
wherein the first portion of the extension plate is in contact with an upper end of the heat shield, and
wherein an outer wall of the pipe is in contact with an inner wall of the second hole in the third portion of the extension plate.

10. The apparatus according to claim 2, wherein each of the pipe, the fixing pin, and the extension plate is formed of stainless steel or molybdenum.

11. A method of growing a silicon single crystal ingot, the method comprising:
lowering, in an upper region of a chamber, a heat shield to a region above a crucible containing a silicon melt using a lifting member;
bringing the heat shield into contact with an upper portion of a thermal insulation member provided in a region outside the crucible;
measuring a first magnitude of a current flowing from the lifting member to the thermal insulation member via the heat shield; and
measuring a second magnitude of the current resulting from further descent of the lifting member to measure, based on a difference between the second magnitude and the first magnitude of the current, a height after the further descent of the lifting member.

12. The method according to claim 11, comprising dipping a seed into the silicon melt to grow a silicon single crystal ingot after measuring the second magnitude of the current flowing from the lifting member to the thermal insulation member via the heat shield.

13. The method according to claim 11, wherein, when a resistivity of the lifting member is represented by ρ, a cross-sectional area of the lifting member in a horizontal direction is represented by S, the first magnitude of the current is represented by I₁, the second magnitude of the current is represented by I₂, and a voltage applied to the current flowing from the lifting member to the thermal insulation member via the heat shield is represented by V, a movement distance (L) of the lifting member from measuring the first magnitude of the current to measuring the second magnitude of the current is calculated using Equation 1 below:
$$L = ( S / ϱ ) \times ( V / {I}_{2} - {I}_{1} ) ) . \qquad < Equation 1 >$$

14. The method according to claim 13, wherein a first water cooling pipe is disposed around a region for drawing-up of the silicon single crystal ingot in the upper region of the chamber,
wherein the lifting member includes:
a fixing pin fixed to an upper portion of the heat shield;
an extension plate fixed to the upper portion of the heat shield by the fixing pin and extending in a horizontal direction from the fixing pin;
a pipe extending upward from the extension plate to an outside of the chamber; and
a body extending from the pipe in an inward direction of the chamber,
wherein a second water cooling pipe extends downward from an inner side of the body,
wherein the second water cooling pipe is disposed below the first water cooling pipe, and
wherein a width of the second water cooling pipe in a lateral direction is greater than a width of the first water cooling pipe in the lateral direction.

15. The method according to claim 14, wherein, based on the calculated movement distance (L) of the lifting member in an upward-downward direction, a change in length of the second water cooling pipe is calculated, and a total length of the first water cooling pipe and the second water cooling pipe in a vertical direction is obtained, the total length of the first water cooling pipe and the second water cooling pipe in the vertical direction being a distance from an upper end of the first water cooling pipe to a lower end of the second water cooling pipe.

16. The method according to claim 1, wherein the heat shield comprises:
a seating portion disposed on an upper end of the thermal insulation member;
a shielding portion disposed above the silicon melt; and
a connecting portion interconnecting the seating portion and the shielding portion.

17. The method according to claim 2, wherein the extension plate is provided with a step.

18. The method according to claim 2, wherein the body is integrally formed with the pipe so as to move up and down together with the pipe.

19. The method according to claim 2, wherein the body is integrally formed with the pipe so as to move up and down together with the pipe.

20. The method according to claim 2, wherein the body is integrally formed with the pipe so as to move up and down together with the pipe.
